(19) United States
(12) Patent Application Publication
(10) Pub. No.: US 2025/0041899 A1
(43) Pub. Date: Feb. 6, 2025

(54) PMUT With Partially Inactive Piezoelectric

(71) Applicant: InvenSense, Inc., San Jose, CA (US)

(72) Inventors: Benjamin Eric Eovino, Oakland, CA (US); Stefon Eric Shelton, Oakland, CA (US); Fabian Thomas Goericke, Berkeley, CA (US)

(21) Appl. No.: 18/403,964

(22) Filed: Jan. 4, 2024

Related U.S. Application Data
(60) Provisional application No. 63/530,560, filed on Aug. 3, 2023.

(51) Int. Cl. B06B 1/06; H10N 39/00

(52) U.S. Cl. CPC B06B 1/0651; H10N 39/00

(57) ABSTRACT

A piezoelectric micromachined ultrasound transducer (PMUT) device has different transduction efficiency at different portions of the PMUT device depending on design characteristics such as materials, material thicknesses, and shape. A metal layer of the PMUT device is patterned to render certain portions of the piezoelectric layer of the PMUT device inactive. Only the active portions of the piezoelectric layer are utilized for transmission and reception of ultrasonic signals, while overall PMUT device capacitance is reduced due to the lack of an active capacitor in the inactive region(s) of the PMUT device, resulting in a PMUT design with increased sensitivity. For differential PMUT devices, the patterning may be performed to match capacitances associated with the differential piezoelectric regions.

### CROSS-REFERENCE TO RELATED APPLICATIONS

This application claims priority to U.S. Provisional Patent Application No. 63/530,560 entitled “PMUT With Partially Inactive Piezoelectric” and filed on Aug. 3, 2023, which is incorporated by reference herein in its entirety.

### BACKGROUND

A device such as a piezoelectric micromachined ultrasound transducer (PMUT) device may be utilized in a variety of applications such as fingerprint sensing, time-of-flight sensing, and medical imaging. The PMUT device may include a piezoelectric material that provides an electro-mechanical response based on a given input signal, which in turn is provided via conductive (e.g., metal) layers located adjacent to the piezoelectric material. When an electrical signal is applied to the piezoelectric material via the conductive layers, the piezoelectric material may exhibit a mechanical response (e.g., generate an ultrasonic output signal) in accordance with the characteristics of the electrical signal. In response to a received mechanical (e.g., ultrasonic) signal, the piezoelectric material may generate a corresponding electrical response that may be sensed via the metal layers.

The piezoelectric layer and metal layers may be stacked over a PMUT membrane layer, such that the piezoelectric layer defines a dielectric volume between the metal layers, resulting in a capacitor having characteristics based on the metal layer materials, metal layer shapes, piezoelectric layer material, and piezoelectric material thickness. A larger capacitance of such a capacitor may result in mismatches with associated PMUT circuitry such as transmit and receive circuits, resulting in a decreased signal-to-noise ratio for the PMUT device and stability issues due to excessive or mismatched capacitances. Modifications to a PMUT design to reduce this capacitance also impact the mechanical response of the PMUT, for example, by reducing the sensitivity of the PMUT design.

### SUMMARY

In an embodiment of the present disclosure, a piezoelectric micromachined ultrasonic transducer (PMUT) comprises a PMUT membrane layer, a first metal layer, a second metal layer, and a piezoelectric layer patterned into at least a first piezoelectric layer portion over only some of the PMUT membrane layer. The first piezoelectric layer portion is at least partially located between the first metal layer and the second metal layer, wherein the first metal layer is patterned to define an active region of the first piezoelectric layer portion and an inactive region of the first piezoelectric layer portion.

In an embodiment of the present disclosure, a method for selecting a patterning of a metal layer of a piezoelectric micromachined ultrasonic transducer (PMUT) comprises providing an initial configuration of a piezoelectric layer located between a first metal layer and a second metal layer over a portion of a PMUT membrane layer. The method may further comprise determining a vibration modeshape of the PMUT and identifying, based on the modeshape properties in the piezoelectric layer, one or more portions of the piezoelectric layer that have a higher transduction efficiency compared to other portions of the piezoelectric layer. The method may further comprise patterning the first metal layer such that the one or more portions of the piezoelectric layer are active regions of the piezoelectric layer and the other portions of the piezoelectric layer are inactive regions of the piezoelectric layer.

In an embodiment of the present disclosure, a process for designing a piezoelectric micromachined ultrasonic transducer (PMUT) may comprise providing an initial configuration of a piezoelectric layer located between a first metal layer and a second metal layer over a portion of a PMUT membrane layer and patterning one of the first metal layer or the second metal layer to modify a capacitive parameter of the PMUT without substantially impacting structural mechanics of the PMUT.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS system with a PMUT device in accordance with an embodiment of the present disclosure;

FIG. 2 depicts exemplary conventional PMUT devices;

FIG. 3 depicts an exemplary PMUT device including an inactive piezoelectric region in accordance with an embodiment of the present disclosure;

FIG. 4 depicts exemplary conventional differential PMUT devices;

FIG. 5A depicts an exemplary differential PMUT device including a patterned metal layer defining inactive piezoelectric regions in accordance with an embodiment of the present disclosure;

FIG. 5B depicts an exemplary differential PMUT device including a patterned metal layer defining inactive piezoelectric regions in accordance with an associated transduction efficiency pattern in accordance with an embodiment of the present disclosure;

FIG. 6 depicts an exemplary PMUT device including multiple inactive piezoelectric regions and partially removed metal layers in accordance with an embodiment of the present disclosure;

FIG. 7 depicts an exemplary PMUT device including selected inactive piezoelectric regions in accordance with an embodiment of the present disclosure;

FIG. 8 depicts an exemplary PMUT device including a distributed patterned metal layer defining active piezoelectric regions in accordance with an embodiment of the present disclosure;

FIG. 9 depicts improvement of a PMUT device sensitivity based on modification of inactive piezoelectric regions in accordance with an embodiment of the present disclosure; and

FIG. 10 depicts exemplary steps for optimizing a PMUT design with inactive piezoelectric regions in accordance with an embodiment of the present disclosure.

### DETAILED DESCRIPTION

MEMS devices such as piezoelectric micromachined ultrasound transducer (PMUT) devices may be utilized for a variety of applications such as fingerprint sensing, time-of-flight imaging, and medical imaging. The general principle of PMUT devices is that a piezoelectric material produces ultrasonic waves based on an electrical input signal that in turn are transmitted in the direction of the environment of the PMUT device. In many applications, the ultrasonic waves are reflected back in the direction of the PMUT device, in which the piezoelectric material of a PMUT device (e.g., the transmitting device or a dedicated receiving device) receives the reflected ultrasonic signal and generates a corresponding electrical output signal. In this manner, a PMUT device or array of PMUT devices may be operated at a suitable power and frequency to generate ultrasonic signals suitable for providing ultrasonic signals to a region of interest, receiving reflections of those signals, and generating a composite image or other complex outputs based on the reflected signals.

An exemplary PMUT device comprises a number of layers, including a piezoelectric layer of a material that generates a mechanical response to an applied electrical signal (e.g., to generate a desired ultrasonic output signal) and an electrical signal in response to an applied mechanical force (e.g., from a received reflected ultrasonic signal). The PMUT device may also include processing circuitry (e.g., an integrated processing layer) that includes signal paths and signal processing circuitry (e.g., amplifiers, filters, etc.) for providing and receiving the electrical signals to and from the piezoelectric layer. Electrical signals may be applied to and received from the piezoelectric layer by electrodes formed from a metal layer on opposite sides of the piezoelectric layer.

Processing circuitry utilized with PMUTs (e.g., transmit and/or receive circuits) can typically only accommodate PMUTs with capacitances below a certain value, with the capacitance limit varying depending on the PMUT and circuit design. Further, an increased capacitance may result in increased noise, even where the PMUT operation is otherwise favorable. This linkage between the PMUT mechanical design and electrical characteristics limits the PMUT designs that can be used, for example, the PMUT size, piezoelectric materials, and/or piezoelectric layer thickness. PMUT electrodes are formed from metal layers and are typically either as close to the center or as close to the edge of the PMUT membrane as possible, since these configurations are typically assumed to maximize sensitivity. Capacitance is typically reduced by reducing electrode size, increasing piezoelectric layer thickness, and/or changing piezoelectric materials. These traditional methods of reducing PMUT capacitance also affect the mechanical behavior of the PMUT device, such as the resonance frequency, modeshape, and static deflection.

In accordance with the present disclosure, the electrical and mechanical performance of the sensor are substantially decoupled, allowing favorable mechanical characteristics to be implemented without losing/altering those benefits to reduce capacitance, and resulting is significant improvements to sensor sensitivity (e.g., signal to noise ratio). In designs utilizing a differential PMUT and circuitry, electrical performance improves when the two electrodes are capacitance-matched. By matching capacitances in differential designs without requiring additional modifications to the mechanical design, the overall sensitivity of the differential sensor is substantially improved.

PMUT capacitance is reduced and tuned by patterning the metal (electrode) layer(s) to define specific areas of the piezoelectric layer (e.g., portions of the piezoelectric layer located between the patterned metal layer and another metal layer on the opposite side of the piezoelectric layer) to be inactive while other portions are active. The patterning may be performed by removing portions of the metal layer (e.g., a top metal layer) to electrically isolate the portions of the metal layer. Only some of the isolated portions are then connected to the associated processing circuitry or signals are selectively applied by the processing circuitry such that portions of the piezoelectric layer that are inactive and do not contribute to the transmission or reception of the ultrasonic signals. The corresponding inactive portions of the metal layer also do not contribute to the capacitance of the PMUT device.

The selection of the portions of the metal layer that are active and inactive may be based on the electromechanical transduction efficiency of the PMUT design. For example, the active metal portions and associated active piezoelectric portions may be selected in part based on the portions of the piezoelectric layer that have the highest transduction efficiency. This will vary with PMUT designs based on materials such as piezoelectric materials, layer thicknesses, other device component size and composition (e.g., of a PMUT membrane), board and component stresses, and other design parameters. The active metal layer sizing may further be patterned to achieve a desired reduction in capacitance and/or capacitance matching (e.g., for differential designs), which may scale in a predictable manner (e.g., with PMUT capacitance scaling linearly with electrode area and inversely with piezoelectric film thickness).

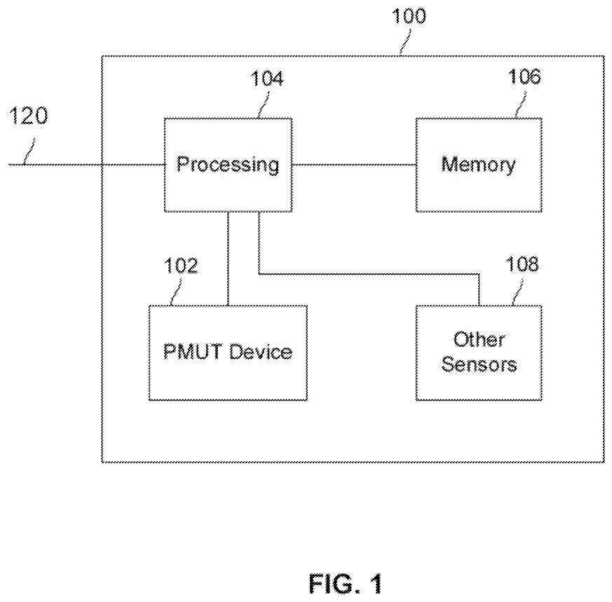

FIG. 1 shows an illustrative PMUT sensor system 100 in accordance with an embodiment of the present disclosure. Although particular components are depicted in FIG. 1, it will be understood that other suitable combinations of the MEMS, processing components, memory, and other circuitry may be utilized as necessary for different applications and systems. In an embodiment as described herein, the PMUT sensor system may include at least a PMUT sensor 102 and supporting circuitry such as processing circuitry 104 and memory 106. In some embodiments, one or more additional sensors 108 (e.g., additional PMUT devices, MEMS gyroscopes, MEMS accelerometers, MEMS pressure sensors, compass, etc.) may be included within the PMUT sensor system 100. Although the present disclosure will be described in the context of particular configurations and designs of PMUT sensors, it will be understood that the selective utilization of inactive piezoelectric regions as described of the present disclosure may be utilized with a variety of suitable PMUT types, configurations, shapes, and designs.

Processing circuitry 104 may include one or more components providing processing based on the requirements of the PMUT sensor system 100. In an exemplary PMUT system, this processing circuitry includes typical PMUT components such as transmit and receive circuitry (e.g., charge pumps, receivers, analog front-end, etc.) for communicating and processing ultrasonic signals. In some embodiments, processing circuitry 104 may include hardware control logic that may be integrated within a chip of a sensor (e.g., on a base substrate of a PMUT sensor 102 or other sensors 108, or on an adjacent portion of a chip to the PMUT sensor 102 or other sensors 108) to control the operation of the PMUT sensor 102 or other sensors 108 and perform aspects of processing for the PMUT sensor 102 or the other sensors 108. In some embodiments, the PMUT sensor 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the PMUT sensor 102 by interacting with the hardware control logic and processing signals received from PMUT sensor 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the PMUT sensor 102 or other sensors 108 may communicate directly with external circuitry (e.g., via a serial bus or direct connection to sensor outputs and control inputs), in an embodiment the processing circuitry 104 may process data received from the PMUT sensor 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the PMUT sensor 102 and other sensors 108 into appropriate measurement units (e.g., based on settings provided by other computing units communicating over the communication interface 110) and perform more complex processing to identify information of interest, such as to combine multiple PMUT sensor outputs to appropriately model a 3-dimensional region of interest (e.g., based on time of flight of a transmitted signal received back at the PMUT sensors) such as a fingerprint, an area of medical interest, a room, or a region adjacent to an external surface of a vehicle.

In embodiments of the present disclosure, a PMUT device includes a piezoelectric layer located between two metal layers and over a PMUT membrane layer, although it will be understood that a PMUT as described herein may have other configurations, for example, including a membrane layer covering the metal and piezo layers. Further, in some embodiments a piezoelectric layer may cover other components, such as a surrounding die area of the PMUT device. The piezoelectric layer, based on the particular mechanical design and configuration, has differing transduction efficiencies at different regions of the piezoelectric layer. The configuration of the piezoelectric layer and the metal layers may be optimized such that the active piezoelectric regions (e.g., portions of the piezoelectric layer located between electrically active portions of the metal layer) correspond to those portions of the mechanical design having higher transduction efficiencies, for example, by removing portions of the piezoelectric layer and/or metal layers, and selectively connecting portions of the metal layers to active electrical signal paths for sending and receiving ultrasonic signals. In this manner, the mechanical design (e.g., resulting in a particular transduction efficiency profile for the piezoelectric layer) is decoupled from the electrical design (e.g., the particular configuration of active portions of the metal layer) in a manner that allows for efficient transmission and receiving of ultrasonic signals while limiting an overall capacitance between metal layers, and thus, substantially reducing noise associated with the PMUT capacitance and improving the signal-to-noise ratio of the PMUT sensor.

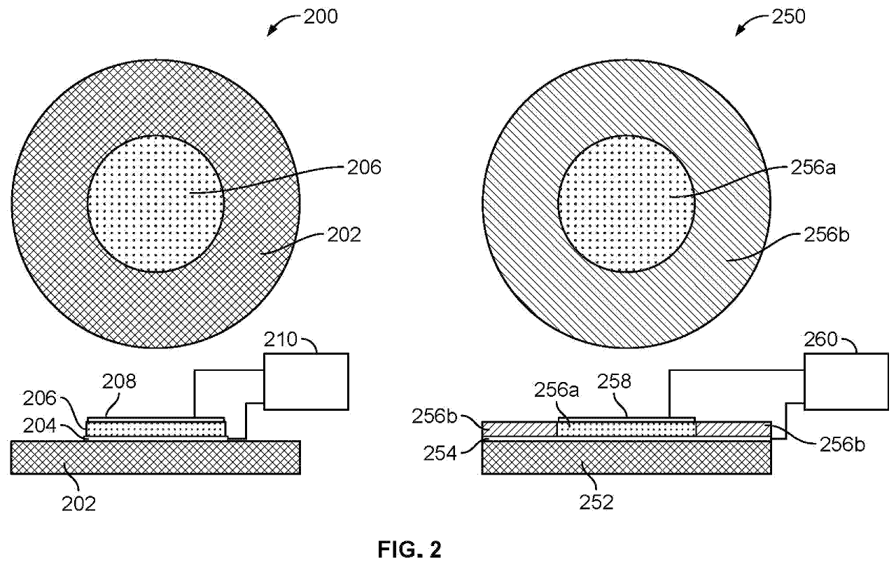

FIG. 2 depicts exemplary conventional PMUT devices. In the typical PMUT devices depicted in FIG. 2, two different PMUT devices 200 and 250 are depicted from a top view and side view, with the top view corresponding to a section view taken from below the top metal layer (e.g., below top metal layers 208 and 258). The particular shape, relative sizing of components and layers, and the like are provided for illustration only, and it will be understood that similar configurations may be achieved with different shapes and relative sizing of components and layers. As can be seen in FIG. 2, each of PMUT device 200 and PMUT device 250 includes a single active piezoelectric region over an entirety of a center portion of piezoelectric layer.

PMUT device 200 includes a PMUT membrane layer 202, a bottom metal layer 204, a piezoelectric layer 206, a top metal layer 208, and processing circuitry 210. The piezoelectric layer 206 is located between top metal layer 208 and bottom metal layer 204. The processing circuitry connects to top metal layer 208 and bottom metal layer 204 to provide for transmission of ultrasonic signals (e.g., by actively applying a signal to top metal layer 208 and/or bottom metal layer 204 to initiate a mechanical response of piezoelectric layer 206 between top metal layer 208 and bottom metal layer 204) and reception of ultrasonic signals (e.g., by receiving electrical signals generated by piezoelectric layer 206 between top metal layer 208 and bottom metal layer 204 in response to received signals such as acoustic signals). The entirety of piezoelectric layer 206 is active in PMUT device 200, resulting in a relatively large capacitor formed between top metal layer 208 and bottom metal layer 204. The configuration of PMUT device 200 results in a vibration modeshape based on the mechanical configuration of the components thereof (e.g., PMUT membrane layer 202, bottom metal layer 204, piezoelectric layer 206, and top metal layer 208) having differing transduction efficiency at different portions of the piezoelectric layer 206, but does not distinguish between active regions of the piezoelectric layer 206 to optimize the average transduction efficiency of the active regions, such that the metal layer electrode coverage is matched to the mechanical performance of the PMUT device 200.

PMUT device 250 is similar to PMUT device 200, with PMUT membrane layer 252 corresponding to PMUT membrane layer 202, bottom metal layer 254 corresponding to bottom metal layer 204, top metal layer 258 corresponding to top metal layer 208, and processing circuitry 260 corresponding to processing circuitry 210. PMUT device 250 includes a single piezoelectric layer 256 including an active piezoelectric layer region 256a located between top metal layer 258 and bottom metal layer 254 and an inactive piezoelectric layer region 256b surrounding active piezoelectric layer region 256a, and covering the entirety of the PMUT membrane layer 252. Because inactive piezoelectric layer region 256b is not located between respective top and bottom metal layers, it does not contribute to the overall capacitance of PMUT device 250, although it does contribute to the overall mechanical response and modeshape of PMUT device 250. Due to the lack of patterning on the piezoelectric layer, the piezoelectric layer cannot have a selectively patterned piezo response, preventing a full and complete optimization of the PMUT design that balances both mechanical response and capacitances. The configuration of PMUT device 250 results in a modeshape based on the mechanical configuration of the components thereof (e.g., PMUT membrane layer 252, bottom metal layer 254, piezoelectric layer portions 256a and 256b, and top metal layer 258) having differing transduction efficiency at different portions of the piezoelectric layer 256a-b, but merely selects a central portion of the piezoelectric layer as the active piezoelectric layer portion 256a, thus potentially failing to optimize for transduction efficiency (e.g., if the portions 256b of the piezoelectric layer were to have higher transduction efficiency) while still maintaining a fairly large capacitance and corresponding reduction in signal-to-noise ratio.

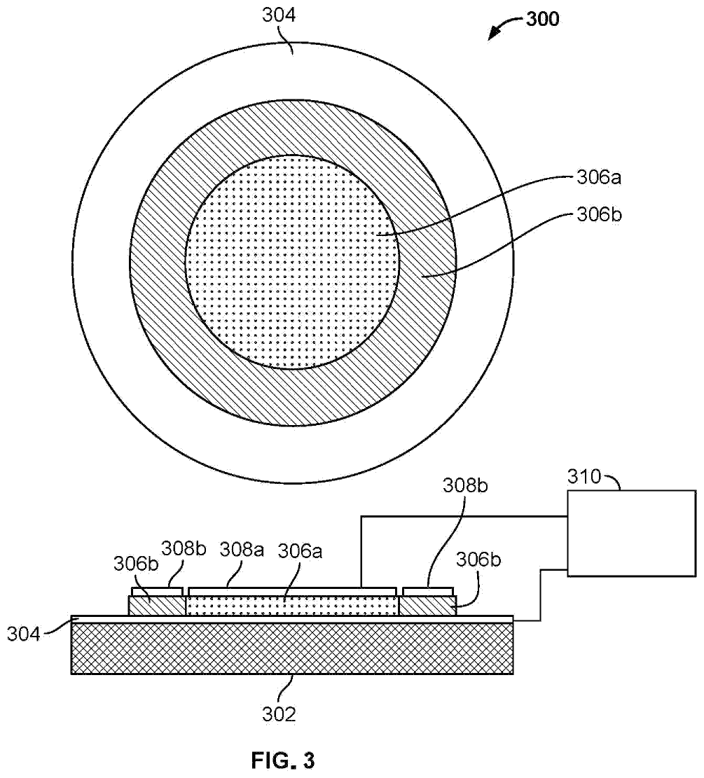

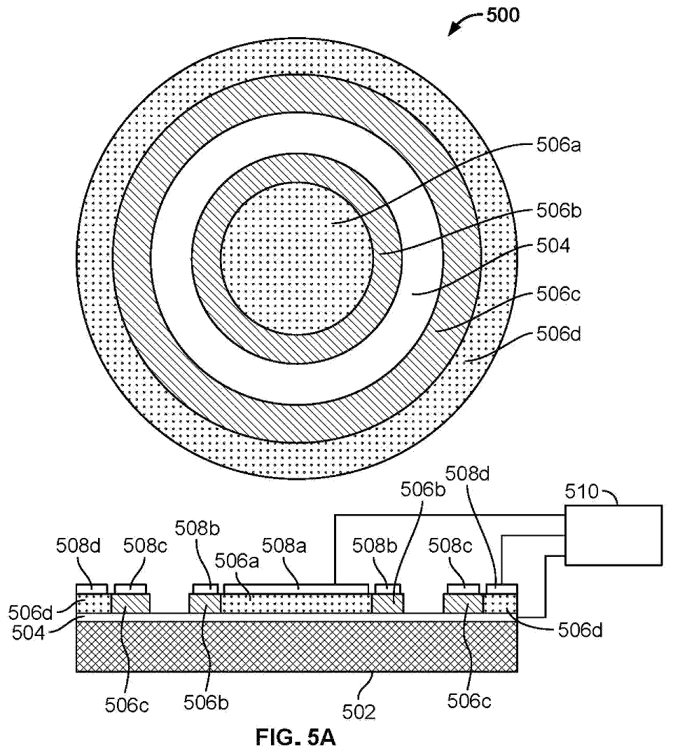

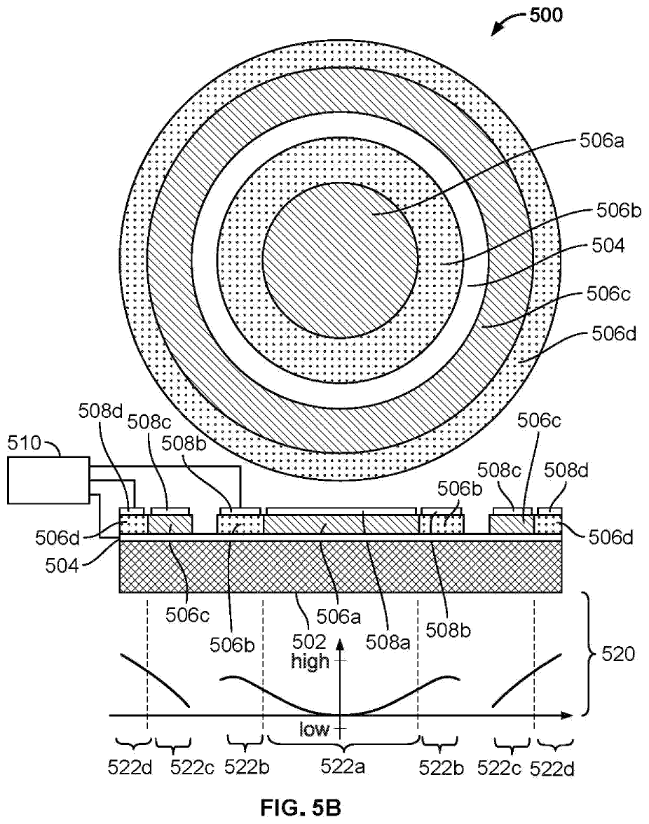

FIG. 3 depicts an exemplary PMUT device including an inactive piezoelectric region in accordance with an embodiment of the present disclosure. Although FIG. 3 will be described in the context of a particular application and system components, it will be understood that the present disclosure may be utilized with a variety of PMUT designs, applications, configurations, shapes, and the like. Although particular components are depicted and described in FIG. 3, it will be understood that components may be added, removed, substituted, or modified in accordance with the present disclosure. For example, in some embodiments patterning may be performed on a bottom metal layer instead of or in addition to patterning of the top metal layer. In the example depicted in FIG. 3, a PMUT device 300 includes a PMUT membrane layer 302, bottom metal layer 304, active piezoelectric layer portion 306a, inactive piezoelectric layer portion 306b, active top metal layer portion 308a, inactive top metal layer portion 308b, and processing circuitry 310. PMUT device 300 is depicted from a top view and side view, with the top view corresponding to a section view taken from below the top metal layer (e.g., below top metal layer portions 308a and 308b) facing towards the other layers. Although particular layers are depicted in a particular order and arrangement in FIG. 3 and other figures depicted and described herein (e.g., FIGS. 5A-8), it will be understood that in some embodiments one or more intermediate layers that are not depicted (e.g., substrates, bonding layers, etc.) may be included.

The piezoelectric layer may be a single layer including two separately shaded portions (e.g., depicted as contiguous in FIG. 3), i.e., an active piezoelectric layer portion 306a and an inactive piezoelectric layer portion 306b. The nomenclature applied to the portions 306a and 306b of the piezoelectric layer is based on the respective patterning and connections of the metal layers 306a and 306b. Collectively with the other components of the PMUT device 300 a certain modeshape is associated with the physical configuration of the piezoelectric layer and other components, such that desirable transduction efficiency characteristics are present at a certain portion of the piezoelectric layer (e.g., piezoelectric layer portion 306a). In the embodiment depicted in FIG. 3, the bottom metal layer 304 is a contiguous layer 304 and is connected to processing circuitry 310 to facilitate transmission and reception of ultrasound signals such as acoustic waves. The top metal layer is patterned as two separate metal layer portions including active top metal layer portion 308a and inactive top metal layer portion 308b. The top metal layer portions are physically separated from each other such that there is no direct electrical connection between the layers, and only one of the top metal layer portions (i.e., the active top metal layer portion 308a) is connected to processing circuitry 310 to facilitate transmission and reception of ultrasound signals such as acoustic waves.

The inactive piezoelectric layer portion 306b is inactive because the inactive top metal layer portion 308b is disconnected from processing circuitry 310, or in some embodiments, is connected to a signal that renders top metal layer portion 308b effectively inactive (e.g., a floating potential, high-impedance ground path, or a same potential or identical signal as bottom metal layer 304). In this manner, the size and shape of the portion piezoelectric layer that is active is selectable by patterning of the top metal layer, for example, in a manner that optimizes transduction efficiency while minimizing capacitance between the active top metal layer portion 308a and bottom metal layer 304. The mechanical performance of the PMUT device remains essentially the same while the overall capacitance is substantially reduced, resulting in an overall improvement in the signal-to-noise ratio for the sensor. In an example where the transduction efficiency is higher near the outside portion of the piezoelectric layer, or at multiple locations of the piezoelectric layer, the location of the active electrodes (e.g., based on the selection of the active portions of the metal layers) may be modified, for example, by connecting the top metal electrode layer portion 308b to the processing circuitry rather than the top metal electrode layer portion 308a. In such an embodiment, the piezoelectric layer portion 306b would be the active piezoelectric layer portion while the inactive piezoelectric portion 306a would not have an associated capacitance that contributes to PMUT noise.

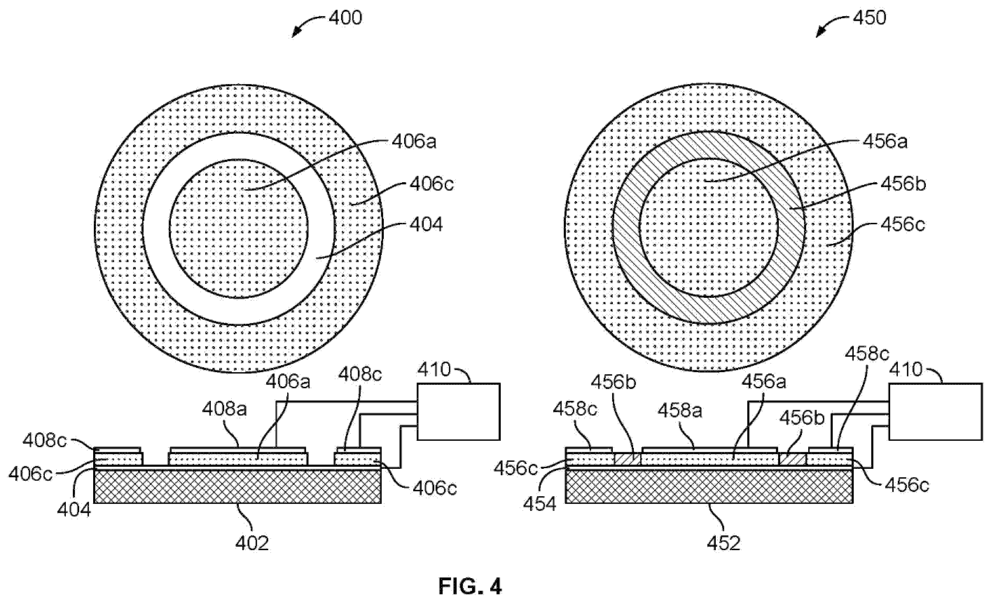

FIG. 4 depicts exemplary conventional differential PMUT devices. In the typical PMUT devices depicted in FIG. 4, two different PMUT devices 400 and 450 are depicted from a top view and side view, with the top view corresponding to a section view taken from below the top metal layer (e.g., below top metal layers 408 and 458). The particular shape, relative sizing of components and layers, and the like are provided for illustration only, and it will be understood that similar configurations may be achieved with different shapes and relative sizing of components and layers. As can be seen in FIG. 4, each of PMUT device 400 and PMUT device 450 is a differential PMUT device having multiple active piezoelectric regions.

PMUT device 400 includes a PMUT membrane layer 402, a bottom metal layer 404, a central piezoelectric layer portion 406a, an outer piezoelectric layer portion 406c, a central top metal layer portion 408a, an outer top metal layer portion 408c, and processing circuitry 410. The central piezoelectric layer portion 406a is located between central top metal layer portion 408a and bottom metal layer 404, each of which are connected to the processing circuitry such that the central piezoelectric portion 406a is active. The outer piezoelectric layer portion 406c is located between outer top metal layer portion 408c and bottom metal layer 404, each of which are connected to the processing circuitry such that the outer piezoelectric portion 406b is active. The signals provided by processing circuitry 410 to the respective central top metal layer portion 408a and outer top metal layer portion 408c are provided in a differential manner to facilitate differential transmission and reception of ultrasonic signals. The entirety of piezoelectric layer is active in PMUT device 400, resulting in a relatively large capacitor formed between top metal layer 408a/c and bottom metal layer 404. The configuration of PMUT device 400 results in a modeshape based on the mechanical configuration of the components thereof (e.g., PMUT membrane layer 402, bottom metal layer 404, piezoelectric layer 406a/c, and top metal layer 408c/b) having differing transduction efficiency at different portions of the piezoelectric layer, but does not distinguish between active regions of the piezoelectric layer to optimize the average transduction efficiency of the active regions, such that the metal layer electrode coverage is inherently linked to the mechanical performance of the PMUT device.

PMUT device 450 is similar to PMUT device 400, with PMUT membrane layer 452 corresponding to PMUT membrane layer 402, bottom metal layer 454 corresponding to bottom metal layer 404, top metal layer portions 458a and 458c corresponding to top metal layer potions 408a and 408c, and processing circuitry 460 corresponding to processing circuitry 410. PMUT device 450 includes a single piezoelectric layer 456 including active piezoelectric layer regions 456a and 456c located between top metal layer portions 458a/458c and bottom metal layer 454 and an inactive piezoelectric layer region 456b located between the active piezoelectric layer portions 456a and 456c. In this manner, inactive piezoelectric layer portion 456b provides a buffer between active piezoelectric layer portions 456a and 456c involved in differential transmission and reception. Because inactive piezoelectric layer region 456b is not located between respective top and bottom metal layers, it does not contribute to the overall capacitance of PMUT device 450, although it does contribute to the overall mechanical response and modeshape of PMUT device 450. The configuration of PMUT device 450 results in a modeshape based on the mechanical configuration of the components thereof (e.g., PMUT membrane layer 452, bottom metal layer 454, piezoelectric layer portions 456a-c, and top metal layer portions 458a/c) having differing transduction efficiency at different portions of the piezoelectric layer 456a-c, but merely selects central and outer portions of the piezoelectric layer as the active piezoelectric layer portions 456a and 456c, thus potentially failing to optimize for transduction efficiency while still maintaining a fairly large capacitance and corresponding reduction in signal-to-noise ratio.

FIG. 5A depicts an exemplary differential PMUT device including a patterned metal layer defining inactive piezoelectric regions in accordance with an embodiment of the present disclosure. Although FIG. 5A will be described in the context of a particular application and system components, it will be understood that the present disclosure may be utilized with a variety of PMUT designs, configurations, shapes, and materials. Although particular components are depicted and described in FIG. 5A, it will be understood that components may be added, removed, substituted, or modified in accordance with the present disclosure. For example, in some embodiments metal layer patterning may be performed on the bottom metal instead of or in addition to the top metal layer. In the example depicted in FIG. 5A, a differential PMUT device 500 includes a PMUT membrane layer 502, bottom metal layer 504, central active piezoelectric layer portion 506a, central inactive piezoelectric layer portion 506b, outer inactive piezoelectric layer portion 506c, outer active piezoelectric layer portion 506d, central active top metal layer portion 508a, central inactive top metal layer portion 508b, outer inactive top metal layer portion 508c, outer active top metal layer portion 508d, and processing circuitry 510. PMUT device 500 is depicted from a top view and side view, with the top view corresponding to a section view taken from below the top metal layer (e.g., below top metal layer portions 508a-508d) facing towards the other layers.

The piezoelectric layer includes a central portion (e.g., including central active piezoelectric portion 506a and central inactive piezoelectric portion 506b, depicted as contiguous in the embodiment of FIG. 5) and an outer portion (e.g., including outer active piezoelectric portion 506d and outer inactive piezoelectric portion 506c, depicted as contiguous in the embodiment of FIG. 5) to facilitate differential operation. The nomenclature applied to the respective active portions 506a and 506d of the piezoelectric layer is based on the respective patterning and connections of the top metal layer portions 508a, 508b, 508c, and 508d. Collectively with the other components of the PMUT device 500 a certain modeshape is associated with the physical configuration of the piezoelectric layer and other components, such that desirable transduction efficiency characteristics are present at a certain portion of the piezoelectric layer (e.g., the inner portion 506a of the central piezoelectric layer 506a/506b and an outer portion 506d of the outer piezoelectric layer 506c/506d). In the embodiment depicted in FIG. 5, the bottom metal layer 504 is a contiguous layer 504 and is connected to processing circuitry 510 to facilitate transmission and reception of ultrasound signals such as acoustic waves. The top metal layer is patterned as two separate metal layer portions for each region (central and outer) of the differential PMUT, including active central top metal layer portion 508a associated with active central piezoelectric layer portion 506a, inactive central top metal layer portion 508b associated with inactive central piezoelectric layer portion 506b, inactive outer top metal layer portion 508c associated with inactive outer piezoelectric layer portion 506c, and active outer top metal layer portion 508d associated with active outer piezoelectric layer portion 506d. The top metal layer portions are physically separated from each other such that there is no direct electrical connection between the layer portions, and only one of the top metal layer portions for each differential region of the PMUT device (i.e., the active top metal layer portions 508a and 508d) is connected to processing circuitry 510 to facilitate transmission and reception of ultrasound signals such as acoustic waves.

The inactive central piezoelectric layer portion 506b is inactive because the inactive central top metal layer portion 508b is disconnected from processing circuitry 510, or in some embodiments, is connected to a signal that renders top metal layer portion 508a effectively inactive (e.g., a floating potential, high-impedance ground path, or a same potential or identical signal as bottom metal layer 504). Similarly, inactive outer piezoelectric layer portion 506c is inactive because the inactive central top metal layer portion 508c is disconnected from processing circuitry 510. In this manner, the size and shape of the portions of the piezoelectric layer that is active is selectable by patterning of the top metal layer, for example, in a manner that optimizes transduction efficiency while minimizing capacitance between the active top metal layer and bottom metal layer. The mechanical performance of the PMUT device therefore remains essentially the same while the overall capacitance is substantially reduced, resulting in an overall improvement in the signal-to-noise ratio for the sensor. In an example where the transduction efficiency is higher near the outer portion of the central piezoelectric layer portion, the processing circuitry may be actively connected to outer top metal layer portion 508b such that outer piezoelectric region 506b is active. Similarly, in an example where the transduction efficiency is higher near the central portion of the outer piezoelectric layer portion, the processing circuitry may be actively connected to central top metal layer portion 508c such that central piezoelectric region 506c is active. Moreover, the sizing, locations, and configurations of the active top metal layer portions and piezoelectric layer portions may be selected such that transmission and receive response of the piezoelectric layer is matched for differential sensing, as well as to match the capacitances of the active portions for improved differential operation.

FIG. 5B depicts an exemplary differential PMUT device including a patterned metal layer defining inactive piezoelectric regions in accordance with an associated transduction efficiency pattern in accordance with an embodiment of the present disclosure. Although FIG. 5B will be described in the context of a particular application and system components, it will be understood that the present disclosure may be utilized with a variety of PMUT designs, configurations, shapes, and materials. Although particular components are depicted and described in FIG. 5B, it will be understood that components may be added, removed, substituted, or modified in accordance with the present disclosure. In the example depicted in FIG. 5B, the components of the PMUT device 500 are identical to FIG. 5A, except that the active components (e.g., piezoelectric layer portions and top metal layer portions) are selected in accordance with the transduction efficiency pattern 520.

The transduction efficiency of a given piezoelectric region is determined by the local curvature (Laplacian) of the resonance vibration modeshape. The vibration modeshape can be affected by piezoelectric film coverage, device composition, size, film properties and stresses, etc. Accordingly, a selection of piezoelectric layer design and metal layer patterning may be determined based on a particular transduction efficiency pattern (e.g., modeshape) for a particular device, whether determined experimentally or through modelling. In the example transduction efficiency pattern 520 depicted in FIG. 5B, the abscissa is matched to the radial dimensions of the PMUT device 500 while the ordinate corresponds to transduction efficiency (e.g., piezoelectric sensitivity) at the corresponding radial location. Transduction efficiency is only depicted for portions of the PMUT device 500 that include a piezoelectric layer.

As is depicted by transduction efficiency pattern 520, for the central piezoelectric layer region (e.g., corresponding to piezoelectric layer portions 506a and 506b) the transduction efficiency is relatively low within a first transduction efficiency region 522a closer to the center of the region and relatively high within a second transduction efficiency region 522b closer to a periphery of the region. Similarly, for the outer piezoelectric layer region (e.g., corresponding to piezoelectric layer portions 506c and 506d) the transduction efficiency is relatively low within a third transduction efficiency region 522c closer to the center of the region and relatively high within a fourth transduction efficiency region 522d closer to a periphery of the outer region. As between the higher transduction efficiency regions 522b and 522d, the fourth transduction efficiency region 522d may be more efficient than the third transduction efficiency region 522b. The sizing and selection of the active patterned top electrode layer portions (e.g., outer active top metal layer 508d and central active top metal layer 508b) may be determined to match both ultrasonic transmission and reception sensitivity based on both transduction efficiency pattern, as well as capacitance. For example, as depicted in FIG. 5B, it is suitable for outer top metal layer 508d (and thus, associated outer active piezoelectric layer portion 506d) to have a relatively reduced width compared to active central top metal layer 508b (and thus, associated central active piezoelectric layer 506b), since the fourth transduction efficiency region 522d corresponds to a higher efficiency than the second transduction efficiency region 522b. Moreover, because the annular ring region defined by outer active top metal layer 508d surrounds and would otherwise have a greater capacitive surface area than the annular ring region defined by central active top metal layer 508b, the reduced width of outer active top metal layer 508d better matches capacitances between the two portions/regions.

Whether a design has single or multiple (e.g., differential) active transmit and receive regions, a determination or estimate of the resonance vibration modeshape provides a means to optimize the PMUT device operation via patterning of one or more metal layers of the PMUT device. By patterning of one or more metal layers to select portions of the piezoelectric layer to be inactive, typically those with lower transduction efficiency, the overall modeshape of the PMUT is not disturbed or modified, while the overall capacitance of the PMUT device is substantially reduced. As a result, the mechanical (e.g., modeshape) performance of the PMUT device and the electrical (e.g., capacitance and transmission sensitivity) are decoupled and can be individually modified for overall signal-to-noise ratio optimization. This optimization can be performed for any suitable piezoelectric materials, material thickness, PMUT membrane types and materials, shapes, and other PMUT parameters, for example to first identify a desirable design and/or modeshape and then optimize electrical characteristics associated with that design and/or modeshape.

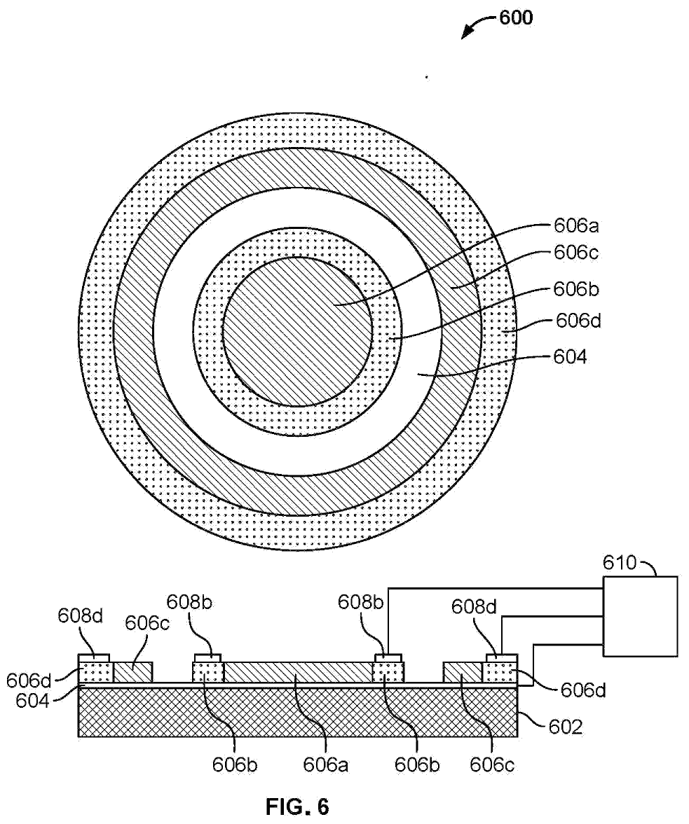

FIG. 6 depicts an exemplary PMUT device including multiple inactive piezoelectric regions and partially removed metal layers in accordance with an embodiment of the present disclosure. Although FIG. 6 will be described in the context of a particular application and system components, it will be understood that the present disclosure may be utilized with a variety of PMUT designs, configurations, shapes, and materials. Although particular components are depicted and described in FIG. 6, it will be understood that components may be added, removed, substituted, or modified in accordance with the present disclosure. For example, in some embodiments metal layer patterning may be performed on the bottom metal instead of or in addition to the top metal layer. In the example depicted in FIG. 6, a differential PMUT device 600 includes a PMUT membrane layer 602, bottom metal layer 604, central inactive piezoelectric layer portion 606a, central active piezoelectric layer portion 606b, outer inactive piezoelectric layer portion 606c, outer active piezoelectric layer portion 606d, central active top metal layer portion 606b, outer active top metal layer portion 608d, and processing circuitry 610. PMUT device 600 is depicted from a top view and side view, with the top view corresponding to a section view taken from below the top metal layer (e.g., below top metal layer portions 608b and 608d) facing towards the other layers.

In the embodiment depicted in FIG. 6, a vibration modeshape may have previously been analyzed to determine that the transduction efficiency of the PMUT device 600 is greatest at portions of the piezoelectric corresponding to outer active piezoelectric layer portion 606d (which may be contiguous with outer inactive piezoelectric layer portion 606c) and central active piezoelectric layer portion 606b (which may be contiguous with central inactive piezoelectric layer portion 606a). Accordingly, an outer active metal layer portion 608d and a central active metal layer portion 608b located above the active piezoelectric layer portions are each connected to processing circuitry 610 for transmission and reception of ultrasonic signals. In the embodiment depicted in FIG. 6, the inactive piezoelectric portions (e.g., central inactive piezoelectric layer portion 606a and outer inactive piezoelectric layer portion 606c) are not covered by a top metal layer. Depending on the fabrication techniques employed, not including inactive metal layer portions or removing the entirety of the inactive metal portions may provide advantages in manufacturing speed and/or yield. If the inactive top metal portions are not deposited in the first instance, material costs may be reduced. Although inactive metal layer portions generally do not contribute significantly to the overall capacitance of the PMUT sensors, not including inactive metal layers may prevent coupling to RF signals, etc., further reducing signal-to-noise ratio.

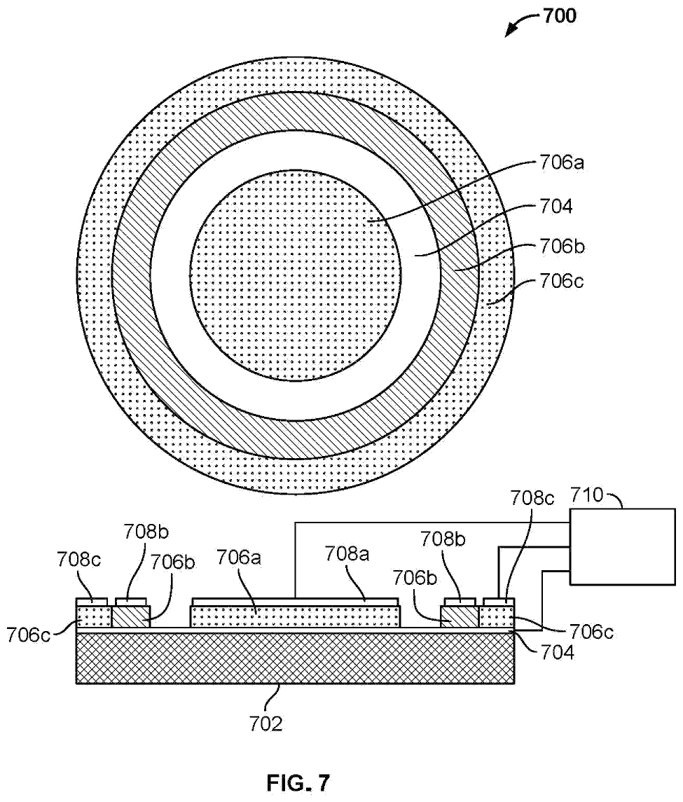

FIG. 7 depicts an exemplary PMUT device including selected inactive piezoelectric regions in accordance with an embodiment of the present disclosure. Although FIG. 7 will be described in the context of a particular application and system components, it will be understood that the present disclosure may be utilized with a variety of PMUT designs, configurations, shapes, and materials. Although particular components are depicted and described in FIG. 7, it will be understood that components may be added, removed, substituted, or modified in accordance with the present disclosure. For example, in some embodiments metal layer patterning may be performed on the bottom metal instead of or in addition to the top metal layer. In the example depicted in FIG. 7, a differential PMUT device 700 includes a PMUT membrane layer 702, bottom metal layer 704, central piezoelectric layer 706a, outer inactive piezoelectric layer portion 706b, outer active piezoelectric layer portion 706c, central top metal layer 706a, outer inactive top metal layer portion 708b, outer active top metal layer portion 708c, and processing circuitry 710. PMUT device 700 is depicted from a top view and side view, with the top view corresponding to a section view taken from below the top metal layer (e.g., below top metal layer portions 708a-708c) facing towards the other layers.

It will be understood that depending on PMUT design, shape, material types (e.g., piezoelectric material, metal layer materials, etc.), material thicknesses, etc., a variety of vibration modeshape and capacitance conditions will be available. The present disclosure enables optimizing PMUT devices by combining any of the piezoelectric and/or metal layer patterning described herein. As an example, in the embodiment of FIG. 7, the vibration modeshape and capacitive response is such that the signal-to-noise ratio is optimized by making the entirety of the central piezoelectric layer 706a active, for example, by not including any top metal layer patterning on central metal layer 708a. A portion of the outer piezoelectric layer (i.e., inactive outer piezoelectric portion 706b) is rendered inactive by patterning the outer metal layer to electrically separate inactive outer metal layer portion 708b from active outer metal layer portion 708c, while only connecting active outer metal layer portion 708c to the processing circuitry 710.

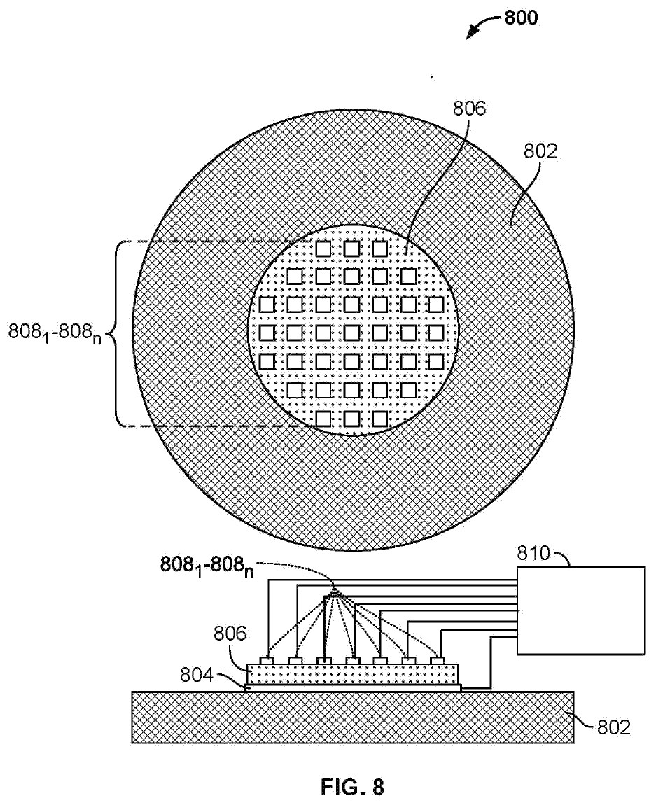

FIG. 8 depicts an exemplary PMUT device including a distributed patterned metal layer defining active piezoelectric regions in accordance with an embodiment of the present disclosure. Although FIG. 8 will be described in the context of a particular application and system components, it will be understood that the present disclosure may be utilized with a variety of PMUT designs, configurations, shapes, and materials. Although particular components are depicted and described in FIG. 8, it will be understood that components may be added, removed, substituted, or modified in accordance with the present disclosure. For example, in some embodiments metal layer patterning may be performed on the bottom metal instead of or in addition to the top metal layer. In the example depicted in FIG. 8, a PMUT device 800 includes a PMUT membrane layer 802, bottom metal layer 804, piezoelectric layer 806, patterned top metal layer portions 808₁-808ₙ, and processing circuitry 810. PMUT device 800 is depicted from a top view and side view.

Embodiments depicted herein have shown circular PMUT devices with circles and surrounding annular ring regions arranged in concentric patterns. It will be understood that the present disclosure similarly applies to other PMUT device shapes and patterns, including but not limited to squares, rectangles, polygons, and other shapes. Further, active and inactive layers may be located in a variety of suitable locations and need not be arranged concentrically, although concentric shapes may be formed as desired for particular end-use applications.

Metal layer patterning, and particularly top metal layer patterning, may be relatively flexible compared to patterning of other layers such as the piezoelectric layer. Accordingly, as is depicted in FIG. 8, a top metal layer may include patterned top metal layer portions 808₁-808ₙ distributed over the piezoelectric layer. In the exemplary embodiment of FIG. 8, each of the patterned metal layer portions is shown individually connected to the processing circuitry, although in some embodiments some or all of the patterned top metal layer portions 808₁-808ₙ may be interconnected such as via recessed traces. The exemplary top metal layer portions 808₁-808ₙ are depicted as square metal layer portions evenly distributed over the piezoelectric layer 806, but may be any desired shape or distribution, for example, to take advantage of particular piezoelectric layer 806 portions having a higher transduction efficiency or to provide for particular desired transmission or reception patterns. In an example of a differential PMUT device (not depicted), complex patterning may be included on one or both of the piezoelectric layer regions.

In some embodiments, active and inactive portions may be selected dynamically by the processing circuitry, for example, by selectively connecting metal layer portions to a particular signal such as a floating potential, ground, or other voltage that renders the metal layer portion and corresponding piezoelectric layer portion inactive. Such selection may provide for different transmission and reception characteristics from a single PMUT device, while retaining the advantage of removing portions of the top metal layer from the overall capacitance. For example, in any of the embodiments of FIG. 3 and FIGS. 5A-7, each of the top metal layers may be connected to the processing circuitry, and selectively rendered active or inactive. In the example of FIG. 8 where all top metal layer portions are individually connected to the processing circuitry, the selective activation of top metal layer portions and piezoelectric layer portions may be performed in any desired pattern overtop metal layer portions 808₁-808ₙ.

In the embodiments described herein, such as with respect to FIGS. 3, 5A, 5B, 6, 7, and 8, patterning may also be performed on the piezoelectric layer itself, for example, by providing a patterning on a piezoelectric layer directly under and/or above a patterned metal layer, which may provide cost reductions and/or yield improvements during manufacturing.

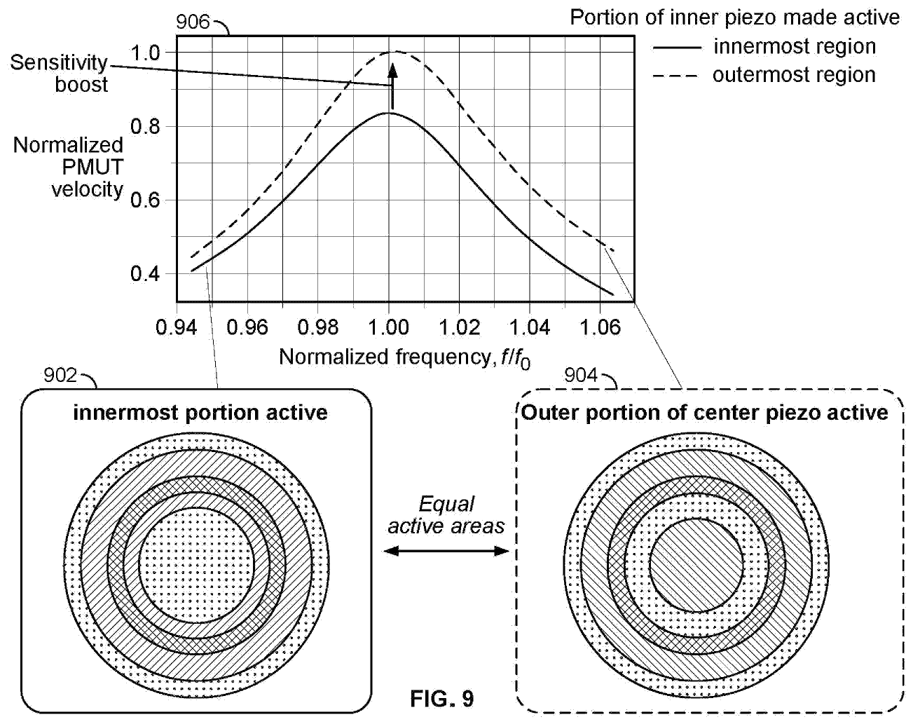

FIG. 9 depicts improvement of a PMUT device sensitivity based on modification of active piezoelectric regions in accordance with an embodiment of the present disclosure. In the example of FIG. 9, a transduction efficiency pattern may correspond to transduction efficiency pattern 520 depicted in FIG. 5B. For PMUT device 902, the active regions are depicted with dotted patterning as the innermost circular portion of the central piezoelectric region and the outermost annular ring portion of the outer piezoelectric region. For PMUT device 904, the active regions are depicted with dotted patterning as the outermost annular ring portion of the central piezoelectric region and the outermost annular ring portion of the outer piezoelectric region. Referring back to FIG. 5B, it will be noted that PMUT device 902 has its active central piezoelectric region corresponding to first transduction efficiency region 522a having a relatively low transduction efficiency, while PMUT device 904 has its active central piezoelectric region corresponding to second transduction efficiency region 522b having a relatively high transduction efficiency. As is depicted by the normalized PMUT velocity plot when driven by an applied voltage 906, there is a substantial efficiency boost simply by utilizing the second transduction efficiency region 522b within the central piezoelectric layer.

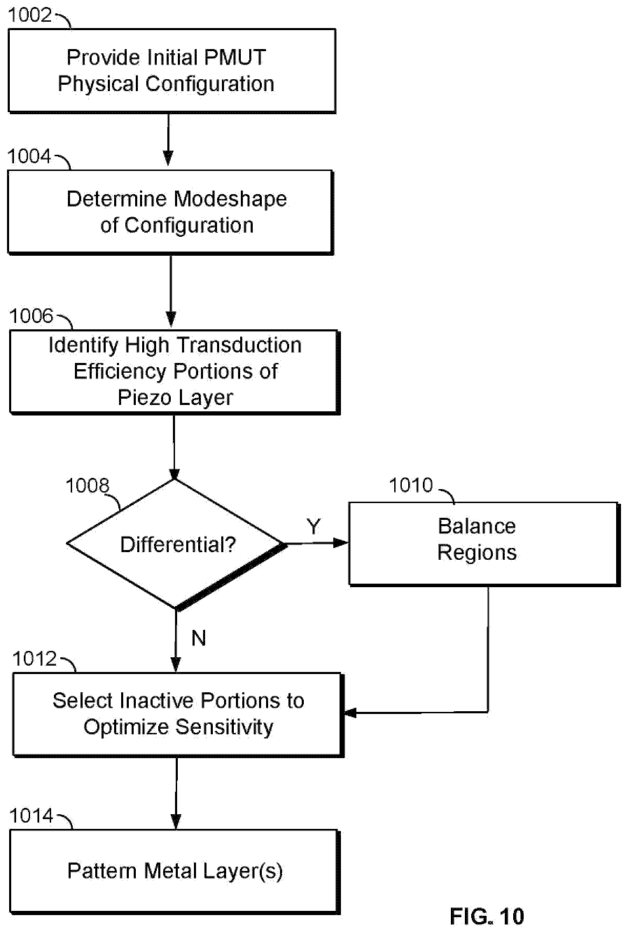

FIG. 10 depicts exemplary steps for optimizing a PMUT design with inactive piezoelectric regions in accordance with an embodiment of the present disclosure. Although particular steps are depicted in a certain order for FIG. 10, steps may be removed, modified, or substituted, and additional steps may be added in certain embodiments, and in some embodiments, the order of certain steps may be modified.

The process starts at step 1002, where an initial PMUT physical configuration is determined. A PMUT physical configuration may be determined based on an end-use application and may be based on a variety of constraints such as desired transmission power, receive sensitivity, frequency response, resonance frequency, component size, fabrication processes, and power consumption. The PMUT physical configuration involves selection and sizing of materials such as metal layers, PMUT membrane layers, and piezoelectric layers, as well as connecting components and materials such as substrates. Once a PMUT physical configuration for the PMUT device is determined, the process may continue to step 1004.

At step 1004, the PMUT device is analyzed to determine the vibration modeshape. This analysis identifies portions of the PMUT device that have differing levels of transduction efficiency. Continuing to step 1006, high transduction efficiency portions of the piezoelectric layer are identified, providing a range of options for rendering portions of the piezoelectric layer inactive. The process may then continue to step 1008.

At step 1008 it may be determined whether the PMUT device design is a differential sensor design. If the design is not differential, the process may continue to step 1012. If the design is differential, processing may continue to step 1010 to balance the inactive and active portions between the respective differential piezoelectric layers of the PMUT device. In an example with a central circular piezoelectric layer region and a surrounding concentric annular ring piezoelectric layer region, the active metal layer coverage of each region may be selected to match closely in overall surface area (e.g., assuming identical materials and thicknesses) and thus match capacitance. The portions of the piezoelectric layer regions covered can then be selected to match overall sensitivity, which may include selecting only those areas with the highest transduction efficiency or in some embodiments may involve selections that match transmit and receive sensitivity. The process may then continue to step 1012.

At step 1012, the inactive portions of the piezoelectric layer may be selected to optimize PMUT device sensitivity. For example, portions of the piezoelectric layer associated with the highest transduction efficiency (e.g., greater than a threshold for a particular application) may be selected, such that lower transduction efficiency regions do not contribute to the overall PMUT device capacitance. The process may then continue to step 1014.

At step 1014, the metal layers are patterned to generate the desired distribution of active versus inactive piezoelectric layer portions. The patterning may be performed in a variety of suitable manners, such as removing material from a metal layer to create electrically isolated metal layer portions, with only the portions associated with the active piezoelectric layer portions connected to active electrical signals. Once the metal layers have been patterned, the process may end.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A piezoelectric micromachined ultrasonic transducer (PMUT), comprising:
a PMUT membrane layer;
a first metal layer;
a second metal layer; and
a piezoelectric layer patterned into at least a first piezoelectric layer portion over only some of the PMUT membrane layer, wherein the first piezoelectric layer portion is at least partially located between the first metal layer and the second metal layer, and wherein the first metal layer is patterned to define an active region of the first piezoelectric layer portion and an inactive region of the first piezoelectric layer portion.

2. The PMUT of claim 1, wherein the first metal layer is located between the PMUT membrane layer and the piezoelectric layer.

3. The PMUT of claim 1, wherein the second metal layer and the piezoelectric layer are located between the PMUT membrane layer and the first metal layer.

4. The PMUT of claim 1, wherein the active region corresponds to a first patterned portion of the first metal layer, and wherein the first patterned portion of the first metal layer is connected to an active electronic signal path for transmitting and receiving signals with the active region of the first piezoelectric layer portion.

5. The PMUT of claim 4, wherein the inactive region corresponds to a second patterned portion of the first metal layer, and wherein the second patterned portion of the first metal layer is at a floating potential or is connected to ground.

6. The PMUT of claim 4, wherein the inactive region corresponds to a portion of the first metal layer that has been removed such that the inactive region is not coupled to the first metal layer.

7. The PMUT of claim 1, wherein the active region corresponds to areas of the piezoelectric layer with a higher transduction efficiency compared to area of the piezoelectric layer corresponding to the inactive region.

8. The PMUT of claim 7, wherein the active region having the higher transduction efficiency is identified based on PMUT vibration modeshape properties in the piezoelectric layer.

9. The PMUT of claim 1, wherein the active region comprises a first active region and the inactive region comprises a first inactive region, wherein a second piezoelectric layer portion is at least partially located between the first metal layer and the second metal layer, and wherein the first metal layer is patterned to define a second active region of the second piezoelectric layer portion and a second inactive region of the second piezoelectric layer portion.

10. The PMUT of claim 9, wherein the first active region corresponds to a first capacitor formed between the first metal layer and the second metal layer and the second active region corresponds to a second capacitor formed between the first metal layer and the second metal layer, and wherein the first capacitor and the second capacitor have substantially matched capacitances.

11. The PMUT of claim 9, wherein the first active region and the second active region have substantially matched transduction efficiencies.

12. The PMUT of claim 9, wherein the first active region corresponds to a first capacitor formed between the first metal layer and the second metal layer and the second active region corresponds to a second capacitor formed between the first metal layer and the second metal layer, and wherein a received acoustic signal generates a first electrical signal output from the first capacitor that is a differential signal compared to a second electrical signal output from the second capacitor.

13. The PMUT of claim 12, wherein a first electrical signal input provided to the first capacitor to generate a first transmitted acoustic signal output from the first capacitor is a differential signal compared to a second electrical signal input provided to the second capacitor to generate a second transmitted acoustic signal.

14. The PMUT of claim 9, wherein the second active region surrounds the first active region.

15. The PMUT of claim 14, wherein the second active region and the first active region form concentric shapes.

16. The PMUT of claim 15, wherein the concentric shapes are a circle for the first active region and at least a portion of an annular ring for the second active region.

17. The PMUT of claim 1, wherein the active region comprises a plurality of separated active regions within the first piezoelectric layer portion.

18. The PMUT of claim 16, wherein the plurality of separated active regions are distributed within the first piezoelectric layer portion.

19. The PMUT of claim 1, wherein the active region comprises a plurality of separated inactive regions within the first piezoelectric layer portion.

20. A method for selecting a patterning of a metal layer of a piezoelectric micromachined ultrasonic transducer (PMUT), comprising:
providing an initial configuration of a piezoelectric layer located between a first metal layer and a second metal layer over a portion of a PMUT membrane layer;
determining a vibration modeshape of the piezoelectric layer;
identifying, based on the modeshape of the piezoelectric layer, one or more portions of the piezoelectric layer that have a higher transduction efficiency compared to other portions of the piezoelectric layer; and
patterning the first metal layer such that the one or more portions of the piezoelectric layer are active regions of the piezoelectric layer and the other portions of the piezoelectric layer are inactive regions of the piezoelectric layer.

21. A method for designing a piezoelectric micromachined ultrasonic transducer (PMUT), comprising:
providing an initial configuration of a piezoelectric layer located between a first metal layer and a second metal layer over a portion of a PMUT membrane layer; and
patterning one of the first metal layer or the second metal layer to modify a capacitive parameter of the PMUT without substantially impacting structural mechanics of the PMUT.
